(19) United States
(12) Patent Application Publication
(10) Pub. No.: US 2025/0095723 A1
(43) Pub. Date: Mar. 20, 2025

(54) IMPROVED SRAM MEMORY INITIALISATION MANAGEMENT DEVICE

(71) Applicant: COMMISSARIAT A L'ENERGIE ATOMIQUE ET AUX ENERGIES ALTERNATIVES, Paris (FR)

(72) Inventors: Jean-Philippe NOEL, Grenoble Cedex (FR); Bastien GIRAUD, Grenoble Cedex (FR)

(73) Assignee: COMMISSARIAT A L'ENERGIE ATOMIQUE ET AUX ENERGIES ALTERNATIVES, Paris (FR)

(21) Appl. No.: 18/882,959

(22) Filed: Sep. 12, 2024

(30) Foreign Application Priority Data
Sep. 19, 2023 (FR) 2309897

(51) Int. Cl. G11C 11/412; G11C 5/14; G11C 11/417

(52) U.S. Cl. CPC G11C 11/412; G11C 5/148; G11C 11/417

(57) ABSTRACT

A control unit of an SRAM memory for triggering an initialisation, selected from different possible distinct initialisation types, of at least one given group of SRAM memory cells of the SRAM memory, the control unit configured to adopt a “locked” operating mode, in which it triggers an initialisation of the given group of cells according to a “default” initialisation type corresponding to a first initialisation type from the different distinct initialisation types or an erasing, and holds at the output the “hard masking” command signal in the same given state as long as a particular so-called “unlocking” signal sequence is not received on the hard masking inputs, the control unit being further configured, subsequently to the reception of the particular so-called “unlocking” signal sequence, to enable the initialisation of the given group according to different initialisation types which may be distinct from the default initialisation.

### TECHNICAL FIELD

The present invention relates to the field of memories, and in particular SRAM-type (SRAM standing for “Static Random Access Memory”) memories, and relates more specifically to that of SRAM memory initialisation.

The present invention implements an improved device allowing managing the selection of an initialisation type from several possible initialisation types of a group of memory cells upon start-up of this group of cells and particular operating modes such as a secure operating mode or particular events such as a detection of fraudulent access to the memory.

### PRIOR ART

There is a reduced number of techniques for initialising an SRAM memory.

A known initialisation type is the so-called “free” initialisation, which consists in powering on, with no constraints, a memory cell layout. With a free initialisation, the state in which each cell is initialised is freely established. In particular, upon a start-up with no constraints of a k-th chip from a very large number Np^{˜}10,000 of produced chips, the cell of the i-th column and of the j-th row has a probability pijk of being initialised at a ‘1’ logic level and a probability 1-pijk of being initialised at a ‘0’ logic level. Over a large number ^{˜}100 of initialisation with no constraints, the average of the initialisation values of the cell of the i-th column and of the j-th row in a memory layout of the k-th chip will tend towards this probability value pᵢⱼₖ. This probability value changes from one cell to another and from one chip to another, such that, over a set of cells of different chips, we will have p statistics that depend in particular on the local variability of its manufacturing process and more generally of PT (“Process”, “Temperature”, i.e. manufacturing process, temperature) conditions, in other words on the local and overall variations of the manufacturing process, on the slew-rate V_{SR} (expressed in Volt/seconds) of the power supply voltage level that are used, and on the operating temperature.

With such an initialisation technique, the initialisation state of the memory or of some cells of the memory could thus make up a digital fingerprint or signature. In particular, for a given k, the cells with a high probability of switching and initialising at a given logic level (pᵢⱼₖ equal or very close to 1 for cells with a high tendency to initialise at ‘1’; and pᵢⱼₖ equal or very close to 0 for cells with a high tendency to initialise at ‘0’) could be used to form this digital fingerprint of the k-th chip.

One drawback of the free initialisation might be that, in the event of a malicious intrusion after such an initialisation, a third-party device could possibly recover this digital fingerprint or signature.

Another so-called “deterministic” initialisation technique consists in writing, one address after another, a predetermined content which may have been set beforehand by the user or the designer of the memory. Among the deterministic initialisation techniques, the “0 setting” type in which the state of each memory cell is forced at a ‘0’ logic value or the “1 setting” type in which the state of each memory cell is forced at a ‘1’ logic value or the “1 setting” type. The implementation of this initialisation type is done here at the expense of the time spent to re-write a given number of memory points at different addresses, at the expense of the associated consumption as well as at the expense of an information leakage related to this re-writing or carried out in a malicious manner during this long operation.

Hence, there is a need to be able to manage different initialisation types and to be able to initialise a set of memory cells according to an initialisation type selected from several distinct initialisation types.

Moreover, the PMOS-type transistors used in the SRAM cells undergo a so-called NBTO (“Negative-Bias Temperature Instability”) physical phenomenon, which results in increasing their threshold voltage, this being all the more true when their dimensions (grid length and width) are reduced. Moreover, this phenomenon is accelerated when the temperature and/or the negative voltage VGS applied between the gate and the source of the transistor increase. An SRAM memory cell is commonly equipped with two inverters connected in a crossed head-to-tail fashion, each being formed in particular of a first P-type transistor and of a second N-type transistor.

The value memorised in an SRAM memory cell will differently influence the PMOS transistors of the same memory cell and the VTP1/VTP2 ratio of the respective threshold voltages of the two PMOS transistors will evolve over time in either direction depending on the memorised value.

Thus, the NBTI phenomenon influences the probability of an SRAM cell being spontaneously initialised upon start-up at the ‘1’ logic level or at its opposite ‘0’ level, whereby the initialisation logic level is related to the VTP1/VTP2 ratio.

Yet, memory data originating from the initialisation of SRAM cells may be used to generate encryption keys or a hardware identifier or a unique digital fingerprint. Thus, they could be used to make up a physical unclonable function (PUF standing for “Physical Unclonable Function”).

In particular, some cells having a high VTP1/VTP2 ratio may be identified as cells that are stable enough to be used to make up a PUF function during a so-called enrolment phase. Nevertheless, because of the effects of the aforementioned NBTI phenomenon, the VTP1/VTP2 ratio could over time be modified, which makes the cells less suitable for use thereof to make up a PUF, one of the prerequisites of which is stability over time on the long run.

A problem related to the effects of the NBTI and which influences the security of the data is the so-called “data imprint” effect (“data imprint effect”). Such an effect is described in the document: “Challenging On-Chip SRAM Security with Boot-State Statistics”, by J. McMahan et al., HOST 2017. When a piece of data stored in memory remains therein for a long time (with the memory in operation, electrically powered), the threshold voltage VTP of the conducting PMOS transistor evolves, due to the same physical effect that causes the NBTI. A harmful remanence or “data imprint” effect then results in that it is possible to find data that have been stored beforehand even though the memory has been reinitialised.

Techniques such as “consumption analysis” (known as “CPA” or “DPA” according to the English acronyms “correlated Power analysis” or “differential power analysis”) may be used to reveal data intended to remain secret, based, inter alia, on this threshold voltage drift phenomenon of the transistors using means for accelerating this drift. Such a technique is described for example in the document: “Power Analysis Resilient SRAM Design Implemented with a 1% Area Overhead Impedance Randomization Unit for Security Applications”, by R. Giterman et al., ESSCIRC 2019.

There is also a need to find a control device intended to manage different initialisation types of a memory and which allows improving the operation of the memory with regards to the effects of the NBTI.

### DISCLOSURE OF THE INVENTION

According to one aspect, the present application relates to a control unit for an SRAM memory able to trigger an initialisation, selected among different possible distinct initialisation types, of at least one given group of SRAM memory cells of said SRAM memory, said control unit comprising:
a first so-called “hard masking” input, able to receive a so-called “detection” signal,
a second so-called “hard masking” input, able to receive a so-called “activation” signal,
one or more so-called “soft masking” input(s) able to receive initialisation indicator signals according to different distinct initialisation types,
   said control unit being configured to adopt a so-called “locked” operating mode, in which, subsequently to a start-up of the memory and irrespective of the value of signals emitted on the first input and the second hard masking input and on the soft masking inputs, or subsequently to the reception of a so-called “locking on said first soft masking input sequence,
   said control unit produces at the output a command signal able to trigger an initialisation of said given group of cells according to a so-called “default” initialisation type corresponding to a first initialisation type from said different distinct initialisation types or an erasing, and holds at the output said command signal in the same given state as long as a particular so-called “unlocking” signal sequence is not received on said hard masking inputs,
   said control unit being further configured, subsequently to the reception of said particular so-called “unlocking” signal sequence on said hard masking inputs, to adopt at least one other operating mode in which, in the absence of new signals or a change in the state of the signals on said hard masking inputs, when said control unit receives an initialisation indicator signal of the first initialisation type, to produce at the output an initialisation command signal of the first type to trigger an initialisation of the memory cells of said given group of cells according to said first initialisation type and when the control unit receives an initialisation indicator signal of the second initialisation type, to produce at the output an initialisation command signal of a second type to trigger an initialisation of the memory cells of said given group of cells according to said second initialisation type.

Advantageously, the detection signal may originate from a module for detecting fraudulent access to said SRAM memory, said locking sequence on said first hard masking input corresponding to a change in the state of said detection signal.

According to a possible implementation, the unlocking sequence May consist, in that order, of a given logic state or a change in the logic state of said detection signal on said first hard masking input into said given logic state and then, a change in the activation signal on said second hard masking input.

In said at least one other operating mode, the control unit may be further configured, subsequently to the reception of said activation signal on the second “hard masking” input and in the absence of a change in the state of the detection signal on the first “hard masking” input, to emit an initialisation command signal of the first type to trigger an initialisation of the memory cells of said given group according to said default initialisation type.

According to a possible implementation, the control unit may be equipped with: an asynchronous flip-flop logic module having a so-called “control” input coupled to the first hard masking input and another so-called “control” input coupled to the second hard masking input, said logic module being configured, subsequently to a start-up or to the reception of said locking sequence, to hold at the output a first logic state as long as said logic module does not receive said unlocking sequence and, subsequently to the reception of said unlocking sequence, to produce at the output a second logic state complementary of said first logic state.

The control unit may further comprise a logic gate stage coupled to an output of said logic module and to said soft masking inputs, said logic gate stage being equipped with:
at least one first logic gate ensuring a given logic function, in particular ensuring an OR function between a first soft masking input and the complementary of an output of said logic module, an output of the first logic gate being coupled to a first output of the control unit intended to output the initialisation command signal of the first type,
at least one second logic gate ensuring a logic function distinct from the given logic function, in particular ensuring an AND function between a second input of said plurality of “soft masking” inputs and the output of said logic module being coupled to a second output of the control unit intended to output the initialisation command signal of the second type.

According to a possible implementation of the control unit, the logic module with an asynchronous flip-flop may be equipped with an asymmetrical asynchronous flip-flop such as an asymmetrical RS flip-flop.

Advantageously, said asynchronous flip-flop may be formed of a first set of transistors ensuring a given logic function, in particular a NOR function or a NAND function, and of a second set of transistors ensuring said same given logic function, said asynchronous flip-flop being asymmetrical so that said first set of transistors is equipped with at least one first group of transistors having an arrangement similar to that of a second group of transistors of said second set of transistors, the transistors of the first group being provided with a threshold voltage different from that of the transistors of said second group.

According to a possible embodiment of the control unit, among said soft masking inputs, mention may be made of:
a first soft masking input is able to receive an initialisation indicator signal of a first initialisation type,
a second soft masking input, able to receive an initialisation indicator signal of a second initialisation type among said different initialisation types, the second initialisation type being distinct from said first initialisation type and from said second initialisation type,
a third soft masking input, able to receive an initialisation indicator signal of a third initialisation type among said different initialisation types, the third initialisation type being distinct from said first initialisation type and from said second initialisation type,
wherein in said at least one other operating mode when the third soft masking input receives an initialisation indicator signal of the third initialisation type, the control unit produces at the input an initialisation command of a third type to trigger an initialisation of the memory cells of said given group of cells according to said third initialisation type.

According to a possible implementation, the first initialisation type and the second initialisation type are distinct initialisation types among:
a “1 setting” or “0 setting” type initialisation consisting in setting all of the cells of said group at the same logic state,
a “random” type initialisation consisting in imposing on each column of cells of said group the same given logic state randomly selected from a first logic state and a second logic state,
a “free” type initialisation consisting in setting the internal nodes of each cell of said group at the same potential and then letting these internal nodes be respectively charged or uncharged in order to let the cell freely settle at a given logic state.

In the locked operating mode, holding at the output of said command signal in the same given state is able to hold said given group of cells in a so-called “metastable” undetermined state for which their respective first storage node and second storage node are set at equal or substantially equal potentials.

According to another aspect, the present application relates to a static random-access memory device comprising:
a set of SRAM cells comprising said given group of SRAM cells,
at least one first control unit as defined before, for initialising said given group of said set of SRAM cells.

Advantageously, the static random-access memory device may further comprise: a second control unit, for controlling the initialisation, according to different possible distinct initialisation types, of the memory cells of a second group of cells of said set of SRAM memory cells distinct from said given group.

Advantageously, the given group of cells may contain a physical unclonable function (PUF), whereas the second group of cells corresponding to sensitive data storage cells or to free-access cells.

According to a possible implementation of the static random-access memory device, the second control unit may be configured, subsequently to each start-up of the memory or subsequently to the reception of a locking signal, to produce at the output an initialisation command signal to trigger an initialisation of said second group of cells according to a default initialisation type among said different distinct initialisation types, the default initialisation type of the second control unit being different from the default initialisation type of the first control unit and selected among:
a “1 setting” or “0 setting” type initialisation consisting in setting all of the cells of said group at the same logic state,
a “random deterministic” type initialisation consisting in imposing on each column of cells of said group the same given logic state selected by random sorting from a first logic state and a second logic state,
a “free” type initialisation consisting in setting the internal nodes of each cell of said group at the same potential and then letting these internal nodes be respectively charged or uncharged in order to let the cell freely settle at a given logic state.

Advantageously, the default initialisation type of the first control unit may be a “1 setting” or “0 setting” type initialisation consisting in setting all of the cells of said group at the same logic state, the default initialisation type of the second control unit being a “random deterministic” type initialisation consisting in imposing on each column of cells of said group the same given logic state randomly selected from a first logic state and a second logic state.

### BRIEF DESCRIPTION OF THE DRAWINGS

The present invention will be better understood upon reading the description of embodiments given, merely as indicative and non-limiting example, with reference to the appended drawings wherein:

FIG. 1 shows an embodiment of a control unit in an SRAM memory capable of triggering an initialisation of at least one first group of cells of an SRAM memory, according to an initialisation type selected from several possible initialisation types.

FIG. 2 shows an example of a truth table to illustrate the operation of the control unit according to FIG. 1.

FIGS. 3A and 3B illustrate different operating modes of an example of a so-called “locking” logic module integrated into a control unit as implemented according to the invention.

FIG. 4 illustrates an example of a structure of the so-called “locking” logic module and equipped in particular with an asynchronous and asymmetrical flip-flop.

FIG. 5 shows an example of an asynchronous and asymmetrical flip-flop that could be provided in a “locking” logic module.

FIG. 6 illustrates a second control unit intended to trigger an initialisation of a second group of cells of an SRAM memory distinct from the group of cells with which the control unit of FIG. 1 is associated.

FIG. 7 illustrates different areas of an SRAM memory layout and each associated with a control unit.

FIG. 8 shows an example of a conventional structure of an SRAM memory cell.

FIG. 9 shows, by means of a time chart, an example of management of the initialisations for different areas of an array of cells and according to different operating modes, normal or secure.

Identical, similar or equivalent parts of the various figures bear the same numerical references so as to facilitate passing from one figure to another.

The various parts shown on the figures are not necessarily shown to a uniform scale, to make the figures more legible.

### DETAILED DISCLOSURE OF PARTICULAR EMBODIMENTS

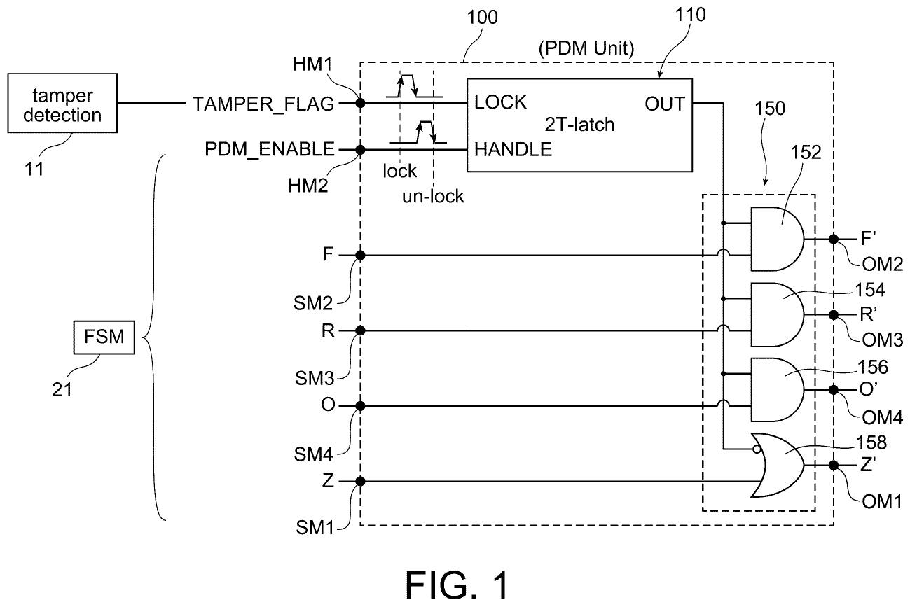

An embodiment of a control unit 100 configured to trigger an initialisation of at least one given group of SRAM cells of an SRAM memory is schematically shown in FIG. 1.

This control unit 100 is able to trigger different distinct initialisation types and allows triggering an initialisation of said at least one given group of cells according to an initialisation type selected from different distinct initialisation types.

This initialisation control unit 100 allows, after start-up of the memory or in a particular operating mode related for example to an intrusion attempt detection, implementing an initialisation according to a so-called “default” initialisation type from the different initialisation types or an erasing of the given group of cells.

This initialisation control unit 100 also allows triggering sequences of several successive initialisations each according to an initialisation type which may be different from the previous one in particular in order to avoid data imprint phenomena (“data imprint”).

The initialisation control unit 100 herein includes a first so-called “hard masking” input HM1 for the reception of a first so-called “detection” logic signal TAMPER_FLAG. For example, this detection signal TAMPER_FLAG may be an indicator signal of an attempt of fraudulent access to the memory and may in particular originate from an intrusion detection module 11. Such a fraudulent access detection module 11 may be equipped with functions similar to those of a TAMP module present in an STM32GO microcontroller commercialised by the STMicroelectronics company and described in the notice “STM32GO-TAMP, tamper and back-up registers, revision 1.0”.

The detection signal TAMPER_FLAG is transmitted in an asynchronous manner and may be such that for example a high state (or a logic ‘1’) indicates an attempt of fraudulent access to the memory.

The initialisation control unit 100 also includes a second so-called “hard masking” input HM2, for the reception of a second so-called “activation” logic signal. This activation signal PDM_ENABLE may originate from a circuit block 21 of the memory forming a state machine (FSM standing for “Finite State Machine”) and made typically from a programmable logic device. Such a device may be provided with at least one register for storing state variables as well as combinatory logic blocks. The changes in the activation signal PDM_ENABLE may depend on different operating modes, for example a normal mode and a secure mode also so-called “crypto” mode in which one wishes to set a group of memory cells.

The control unit 100 includes a so-called first “soft masking” input SM1, provided for the reception of an indicator logic signal Z of a first initialisation type, in this example of the “0 setting” type of the memory cells.

A second soft masking input SM2 is provided for the reception of an indicator logic signal F of a second initialisation type, herein corresponding to a so-called “free” initialisation of memory cells.

A third soft masking input SM3 may also be provided for the reception of an indicator logic signal R of a third initialisation type, herein corresponding to a so-called “random” initialisation (and which may also be so-called “random deterministic” or “random by column”) of memory cells.

In this embodiment, a fourth soft masking input SM4 is also provided for the reception of an indicator logic signal O of a fourth initialisation type in this example of the “1 setting” type of the memory cells.

The indicator signals O, F, R, Z respectively emitted on the inputs SM1, SM2, SM3, SM4 may all originate from the state machine 21 producing the activation signal PDM_ENABLE.

The control unit 100 is herein formed of an asynchronous flip-flop logic module 110 having an input LOCK coupled to the first hard masking input HM1 and another input HANDLE coupled to the second hard masking input HM2. This logic module 110 produces at the output a logic output signal OUT whose state is transmitted to a logic stage 150. In this example, the inputs of the module 110 are directly connected respectively to the hard masking inputs HM1, HM2.

The stage 150 itself is coupled to the soft masking inputs SM1, SM2, SM3, SM4 and produces, according to the value of the output signal OUT of the module 110 and the values of the signals F, R, O, Z each indicator of an initialisation type, one or more initialisation command signals F′, R′, O′, Z′ allowing triggering different initialisation types intended to at least one initialisation circuit.

This initialisation circuit (not shown in this figure) itself is configured to initialise said at least one given group of memory cells, according to different distinct initialisation types according to the received initialisation command signals F′, R′, O′, Z′.

In the illustrated particular embodiment, the logic stage 150 is formed of a set of logic gates 152, 154, 156, 158.

A logic gate 158 of said set of logic gates herein ensures an OR function between the first soft masking input SM1 and the complementary of the output OUT of the module 110 to produce at a first output OM1 of the control unit 100 a so-called “hard masking” command signal Z′ or first initialisation command signal allowing triggering an initialisation of cells according to the so-called “0 setting” initialisation type.

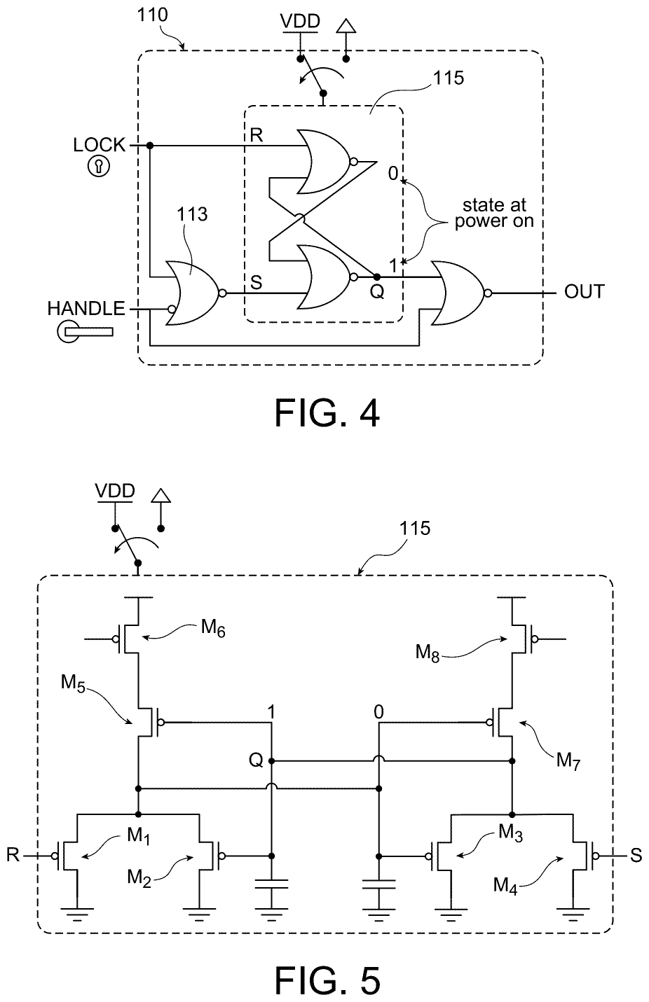

An initialisation circuit of the same type as that one described in the application No. 2111286, in particular in connection with its FIG. 4, may be triggered by the signal Z′ in order to allow writing al of the memory cells at “0” and thus implementing a “0 setting” type initialisation.

A second initialisation command signal F′, of another initialisation type different from the command signal Z′, could be produced on a second output OM2 of the control unit 100 and in particular by means of a logic gate 152 of the stage 150. In this example, this gate 152 ensures a logic function different from that of the gate 158, herein an AND function, between the second soft masking input SM2 and the output OUT of the module 110. The initialisation control signal F′ is herein intended to trigger an initialisation of said group of cells according to a “free” type initialisation.

Reference could be made to a French patent application No. 2111286 filed by the Applicant on Oct. 25, 2021 before the National Institute which describes an initialisation circuit of the SRAM memory, configured to implement a free-type initialisation. This “free” initialisation type consists in letting each memory cell be initialised at a specific value during the progressive start-up of the elements making up the memory cells, in particular two looped inverters as illustrated in FIG. 8, without trying to impose a “0” or “1” value on the internal nodes N_{T} and N_{F} of the cell. In the free initialisation mode, the access transistors TA_{T} and TA_{F} are non-conducting, the cell being as if it were “isolated” from the other cells and from the rows of bits BLT and BLF.

A third initialisation command signal R′, in this example of the “random” type, of the cells could be produced on a third output OM3 of the control unit 100 by a logic gate 154 of the stage 150 herein ensuring an AND function, between the soft masking input SM3 and the output OUT of the module 110. The third initialisation command signal is herein intended to trigger an initialisation of said group of cells according to a “random” type initialisation.

In another French patent application No. 2213917 filed by the Applicant on Dec. 20, 2022 before the Industrial Property National Institute, an initialisation circuit for implementing a random type initialisation is described. it allows imposing a value on all or part of the cells of the same column; this same value having been defined beforehand by a random sorting process. The expression “random” initialisation is used for this initialisation type proceeding in two steps, random sorting and then forced initialisation. Thus, for this initialisation type, it is possible to have for example all of the cells of a column set in a state corresponding to a logic “0” and all of the cells of a second column set in a state corresponding to a logic “1”, the respective states of these columns being the result of random sortings.

A fourth initialisation command signal O′, in this example of the “1 setting” type, of the cells could be produced on a fourth output OM4 of the control unit 100 by a logic gate 156 of the stage 150 herein ensuring an AND function, between the soft masking input SM4 and the output OUT of the module 110. The fourth initialisation command signal is herein intended to trigger an initialisation of said group of cells according to a “‘1’ setting” type initialisation.

An initialisation circuit described in the application No. 2111286, in particular in connection with its FIG. 4, allows writing all of the memory cells at “1” and thus implementing a “1 setting” type initialisation. To do so, the memory device provides for controlling, for each column, one of the rows of bits BLT or BLF by connecting it to a supply voltage by activation of a bit row selection transistor. Thus, the selected and powered row of bits tends to impose a “1” or “0” value on one of the nodes of each memory cell connected to this row of bits.

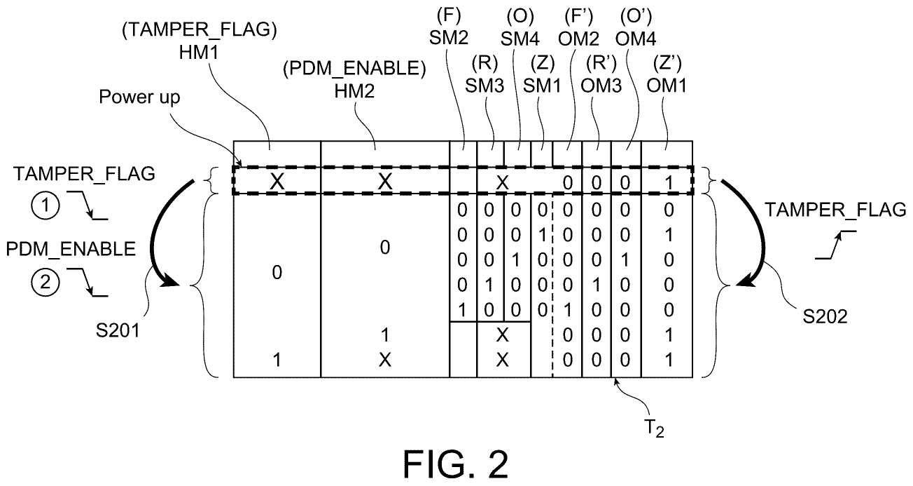

An example of a truth table T₂ illustrating the operation of the control unit 100 of FIG. 1 is given in FIG. 2.

The initialisation control unit 100 is configured to adopt a so-called “locked” operating mode (first row of the truth table) in which the initialisation control unit 10 is configured so that, subsequently to a start-up, irrespective of the value of signals emitted on the first hard masking input HM1, on the second hard masking input HM2 and on the soft masking inputs SM1, SM2, SM3, SM4, the control unit produces at the output a command signal allowing triggering an initialisation of said given group of cells according to a so-called “default” initialisation type or an erasing of said given group of cells prior to setting of this given group of cells in a metastable state.

In the so-called “default” operating mode, the logic module 110 is set in a so-called “locked” state and produces at the output OUT the same given logic state, for example OUT=‘0’, as long as it does not receive a so-called unlocking sequence to get it out of this given state.

The given state of the signal Z′ emitted on the first output OM1 could cause an erasing of the data and setting of said at least one group of cells in a so-called “metastable” state for which their first node and second node are set at equal or substantially equal potentials, in particular when the given group of cells associated with the control unit 100 are intended to ensure a physical unclonable function (PUF). The French patent application No. 2214117 filed by the Applicant on Dec. 21, 2022 before the Intellectual Property National Institute provides for a circuit configured to trigger such an erasing and setting in a metastable state. Thus, the first output OM1 may be coupled to such a circuit type. During an operation of erasing the memory, the internal nodes of the memory cells may be positioned at identical or substantially identical values (i.e. which differ by less than 10 mV), either by short-circuiting, or by discharge of the nodes following a power supply cut-off. Hence, a possible initialisation phase consists in making a memory cell switch from an “undetermined” (and undeterminable by reading) state into a state with a “determined” (and therefore determinable by reading) memorised value. The present application follows other patent applications of the Applicant in connection with the subject of SRAM memory devices. Reference may also be made to the FR patent application, No. 1761692, filed on Dec. 6, 2017 in which an erase mechanism is described. Reference may also be made to the French patent application No. 2111286 filed by the Applicant on Oct. 25, 2021 before the Intellectual Property National Institute in which an erasing is also described.

Alternatively, when the given group of cells associated with the control unit 100 are intended to store sensitive data CSP (standing for “Critical Security Parameters”), the signal Z′ emitted on the first output OM1 could cause an initialisation of this given group according to the so-called “default” initialisation type. In the illustrated particular embodiment, the default initialisation type corresponds to the first initialisation type, in other words to a “0 setting” type initialisation of the cells. Thus, the command signal Z′ could allow triggering an initialisation of the cells by “0 setting”. This signal Z′ on the output OM1 (herein corresponding to a 1 logic state) herein allows, subsequently to a start-up of the memory, triggering a 0 setting of the cells of a group of cells associated with the control unit 100. By “0 setting” of the cells, it should herein be understood setting at a potential of their first node or of their second node corresponding to a logic ‘0’ according to which these complementary nodes is conventionally supposed to establish the logic state of the cell.

A particular sequence of the hard masking signals on the inputs HM1 and HM2 allows getting out of the “default” operating mode. Advantageously, the unlocking sequence may correspond to a series of signals on the first hard masking input HM1 and then on the second hard masking input HM2.

In the particular embodiment illustrated in FIG. 2, an unlocking sequence S201 consists in applying a given logic state, for example a logic ‘0’ on the first hard masking input, and then applying a falling edge (i.e. a passage from a logic ‘1’ into a logic ‘0’) on the second hard masking input.

After reception of such a sequence, the logic module 110 is no longer in its locked state and its output is no longer necessarily in the ‘0’ logic state and could thus be modified.

A “soft masking” operating mode could then be established as long as no new signals or change in the state of the signals on the hard masking inputs HM1, HM2 is detected, which amounts in this example in holding in state, in particular a low state or a ‘0’ logic level, on the inputs HM1, HM2, the soft masking signals control the initialisation.

Thus, in this soft masking mode, when the control unit 100 receives a “0 setting type” initialisation indicator signal Z on its input SM1 (third row of the truth table), the control unit 100 produces at the output a “0 setting” type initialisation command signal Z′ to trigger an initialisation of the memory cells by performing a setting of these cells in a ‘0’ logic state.

In the soft masking mode, when the control unit receives a free-type initialisation indicator signal F on its input SM2 (sixth row of the truth table), the control unit 100 produces at the output a free-type initialisation command signal F′ to trigger a “free”-type initialisation of the memory cells.

When the control unit 100 receives a random initialisation indicator signal R′ on its input SM3 (fifth row of the truth table), it produces at the output a “random”-type initialisation command signal R′ to trigger a random initialisation of the memory cells.

When the initialisation management unit receives a “1 setting” type initialisation indicator signal O on its input SM4 (fourth row of the truth table), the control unit 100 produces at the output a “1 setting” type initialisation command signal O′ to trigger a random initialisation of the memory cells by carrying out setting of these cells in a ‘1’ logic state

Thus, when a given soft masking input SM1, SM2, SM3, SM4, receives an initialisation indicator signal of a given initialisation type, the control unit produces at the output an initialisation command signal to trigger an initialisation of the memory cells of the given sector according to said given initialisation type.

When the module 110 is unlocked, the reception of an activation signal on the second hard masking input HM2, which amounts in this example in setting the signal PDM_ENABLE at 1, leads, as long as no intrusion detection signal is detected (reflected in this example by TAMPER_FLAG=‘0’) to an operating mode in which, irrespective of the signals emitted on the soft masking inputs SM1, SM2, SM3, SM4, a command signal is emitted on the output OM4 to trigger a default initialisation, herein of the ‘0’ setting type on the group of cells associated with the control unit 100.

The initialisation control unit 100 is configured to adopt again the so-called “default” operating mode subsequently to the reception of a locking signal or indicator on said first hard masking input HM1.

Thus, such a signal or indicator causes locking S202 of the output OUT of the module 110.

This locking is implemented by detection of a new sequence S202, for example when a rising edge (passage from logic ‘0’ into a logic ‘1’) on the intrusion detection signal TAMPER_FLAG is detected. Following such a detection, the control unit 100 operates again in its default mode in which, irrespective of the value of the hard masking and soft masking inputs, a “default” initialisation command logic signal is produced, in this example in the form of a “0 setting” type initialisation command signal produced at the output OM4 of the control unit 100.

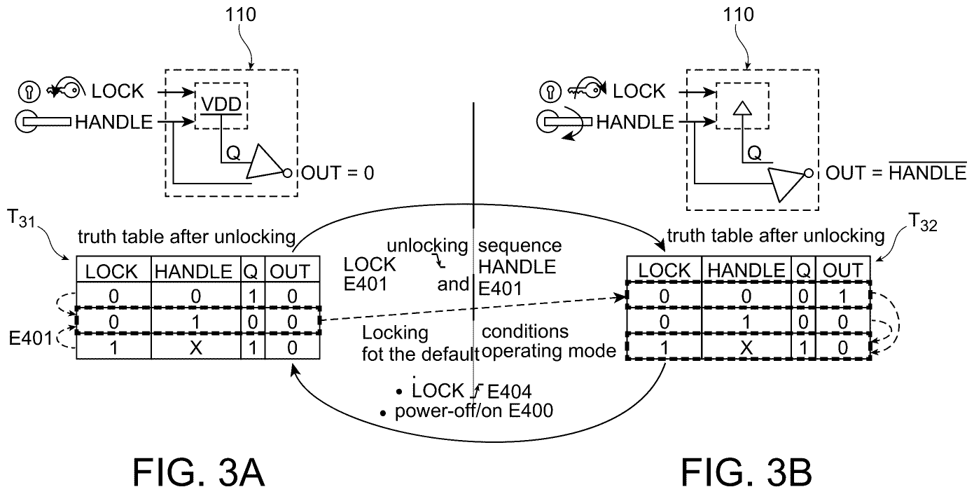

In FIGS. 3A, 3B, different operating modes of the logic module 110 are illustrated by means of a first truth table T₃₁ and of a second truth table T₃₂.

Subsequently to a start-up (step E400 herein corresponding to a setting of a power supply rail of the module 110 at VDD), the output OUT of the module is always initialised at the same logic state, herein for example a logic state OUT=‘0’, and that being so, irrespective of the value of its control inputs LOCK and HANDLE, themselves corresponding to the hard masking inputs.

The module 100 is then (truth table T₃₁) in the “locked” operating mode of the control unit 100 and in which its output OUT remains always in the same logic state, herein at ‘0’.

The particular unlocking sequence (steps E401 and then E402) for making the module 110 get out of its “locked” state, consists for example in applying a 0 on the input LOCK before applying a falling edge on the input HANDLE. Thus, subsequently to the reception of the unlocking sequence, the output signal OUT of the module 110 switches from the “locked” state upon start-up of the power supply, in this example ‘0’, into another state, in this example ‘1’. This allows leaving the default operating mode of the previously-described control unit.

Afterwards, in an “unlocked” operating mode (truth table T₃₂), the output OUT could have its state changed.

In the “unlocked” operating mode of the module 110, the output OUT can switch again into a ‘0’ logic state allowing triggering a “default” type initialisation (i.e. in the previously-described embodiment corresponding to a “0 setting” type initialisation) yet without resetting the module 110 into a locked state. This is done by switching the signal on the input HANDLE to ‘1’.

To set the module 110 again in a “locked” state (step E404), the signal on the input LOCK is set at 1.

Before extinction of the power supply, it is possible to provide for applying the locking signal and setting the input LOCK at ‘1’ in order to ensure that, after it has been power again, the logic module 110 actually restarts in the default state without being affected by a remanence effect of the lastly memorised data.

This setting of the input LOCK in a ‘1’ logic state may correspond to an activation or setting in a ‘1’ logic state of the “Tamper_Flag” signal subsequent to a detection of a power supply voltage drop. For example, such a detection is implemented by an external fraudulent access detection module or circuit.

FIG. 4 is intended to illustrate a detailed embodiment of the aforementioned logic module 110 and receiving the hard masking signals originating from the hard masking inputs HM1, HM2, respectively on a first control input LOCK and a second control input HANDLE. The logic module 110 herein integrates an asynchronous flip-flop 115, in particular an RS flip-flop, whose input R is coupled to the first control input LOCK. The output of a logic gate 113 ensuring a logic function between the first control input LOCK and the second control input HANDLE is applied at the input S of the flip-flop. For example, the logic gate 113 ensures a NAND function between the first control input LOCK and the complementary of the second control input HANDLE. The output Q of the flip-flop 115 is coupled to a logic gate 117 ensuring for example a NOR function and delivering the output signal OUT of the module 110.

The asynchronous flip-flop 115 is particular in that it is asymmetrical, so that, when it is powered on (schematically illustrated in FIG. 4 by switch from the ground into a potential VDD of its power supply), it is always initialised at the same logic state, herein for example a ‘1’ logic state on the output Q.

The RS-type asynchronous flip-flop 115 may be made asymmetrical, by asymmetrically sizing the two NOR or NAND gates that compose this flip-flop 115. Thus, by design, the initialisation value of the module 110 when the latter is power on determined.

A particular embodiment of an asymmetrical RS flip-flop 115 is given in FIG. 5.

The flip-flop 115 is formed of a first set of transistors M1, M2, M5, M6 herein ensuring a NOR logic function and of a second set of transistors M3, M4, M7, M8 ensuring the same logic function as the first set of transistors M1, M2, M5, M6.

The first set of transistors includes a first group of transistors M1, M2, on this example N-type transistors, having an arrangement similar to that of a second group of N-type transistors M3, M4, but having a lower threshold voltage than that of the transistors M3, M4 of the second group.

To increase the asymmetry, the first set of transistors may be provided with a group of transistors M5, M6, in this example P-type transistors, having an arrangement similar to that of another group of P-type transistors M7, M8, but provided with a higher threshold voltage than that of the transistors M7, M8. Alternatively, or in combination, the asymmetry may also be obtained with different geometries of the transistors relative to one another and in particular by the width W to length L ratio (W/L) of their channel.

Advantageously, it is possible to provide for equipping the same SRAM memory with several initialisation control units of the type of the one described before in connection with FIG. 1, each associated with a particular group of cells from a set of SRAM cells of a memory array.

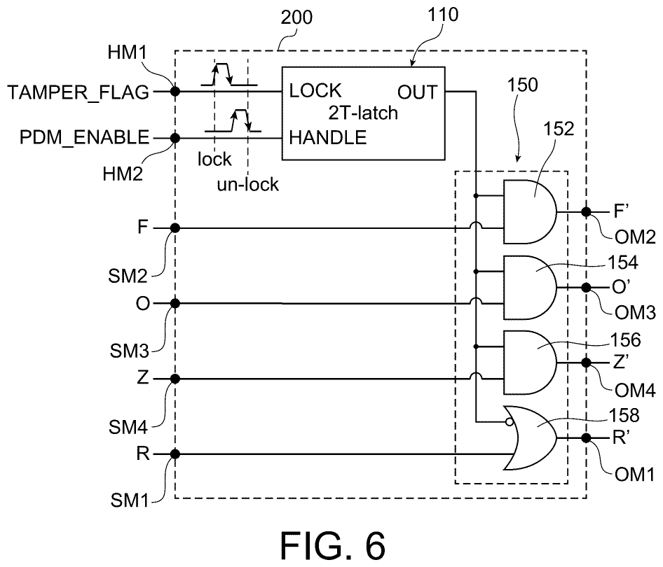

Thus, in FIG. 6, another initialisation control unit 200 for controlling the initialisation of at least one other given group of SRAM cells of the same SRAM memory as that one provided with the group of cells controlled by the initialisation control unit 100 is illustrated.

This other initialisation control unit 200 has a structure similar to that of the control unit 100 but differs in particular from that one described in connection with FIG. 1, in that its default initialisation type corresponds this time to a “random” type initialisation. Hence, in this example, the random initialisation command signal R′ corresponds to the default initialisation command signal. This signal R′ is emitted on the output OM1.

The initialisation indicator signals O, F, R, Z are this time emitted respectively on the inputs SM3, SM2, SM1, SM4, whereas the initialisation command signals O′, F′, R′, Z′ originate this time from the outputs OM3, OM2, OM1, OM4, respectively.

According to a possible implementation, the control unit 100 and the other control unit 200 may be dedicated to the management of the initialisation of groups of cells belonging to different areas of an array or of a memory layout.

Thus, this could allow managing, differently from one area to another of the memory, the sequence of initialisations and also providing for default initialisation types, from one area to another of the memory.

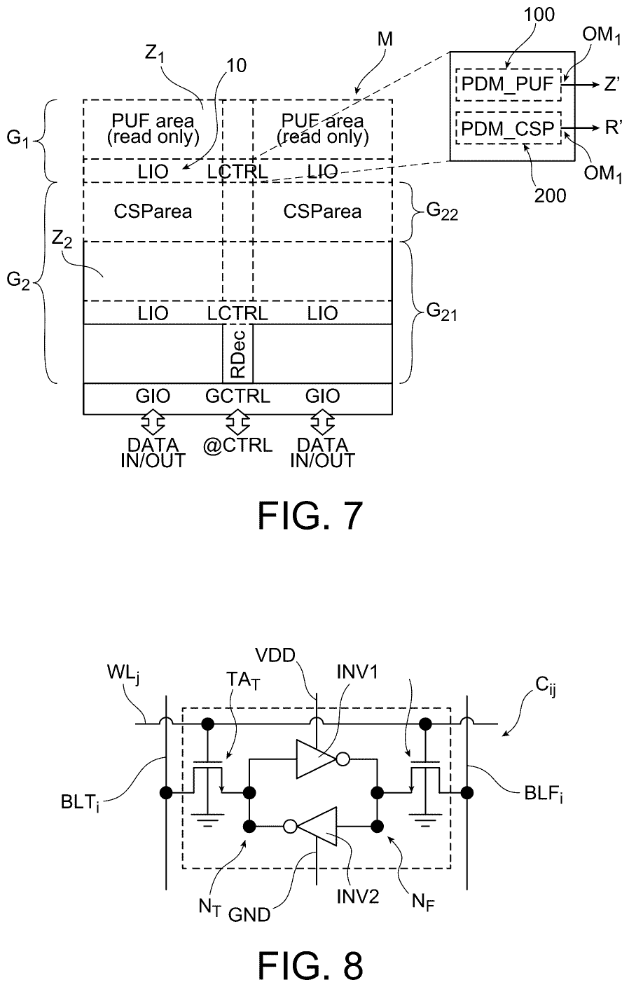

An example of a memory layout is schematically shown in FIG. 7 and comprises an array M of memory cells. The array is typically formed of a plurality of rows and columns of SRAM cells (not shown in this figure). One could herein distinguish two areas Z1, Z2 in the array M, each formed of a group of cells. In particular, the memory includes a first group G1 of cells located in a first area Z1 of the array. According to a particular embodiment, the first area Z1 contains cells intended to ensure a physical unclonable function (PUF) and whose logic state, in particular the initialisation logic state, could be used to form a digital signature or a digital fingerprint of the memory.

The memory also includes a second group G2 located in a second area Z2 of the array typically larger in terms of size than the first area Z1. The second group G2 may be formed of several subgroups G21, G22 and advantageously include a subgroup G22 of cells capable of storing sensitive data CSP (standing for “Critical Security Parameters”).

The memory may then be provided with an initialisation control unit 100 as described for example in connection with FIG. 1 dedicated to the first area Z1 corresponding to the physical unclonable function (PUF). In turn, another control unit 200 as described for example in connection with FIG. 6 may be dedicated to the second area Z2 and intended to control the initialisation of the subgroup G22 of CSP cells that could store sensitive data. Thus, it is possible to manage the default initialisation and the sequencing of the initialisations of the area Z1 dedicated to the PUF differently from those of other areas and in particular of the CSP cells area.

The initialisation control units 100, 200 may be implemented in a region peripheral to the memory cells for example a region in which a row or column controller of the array is located.

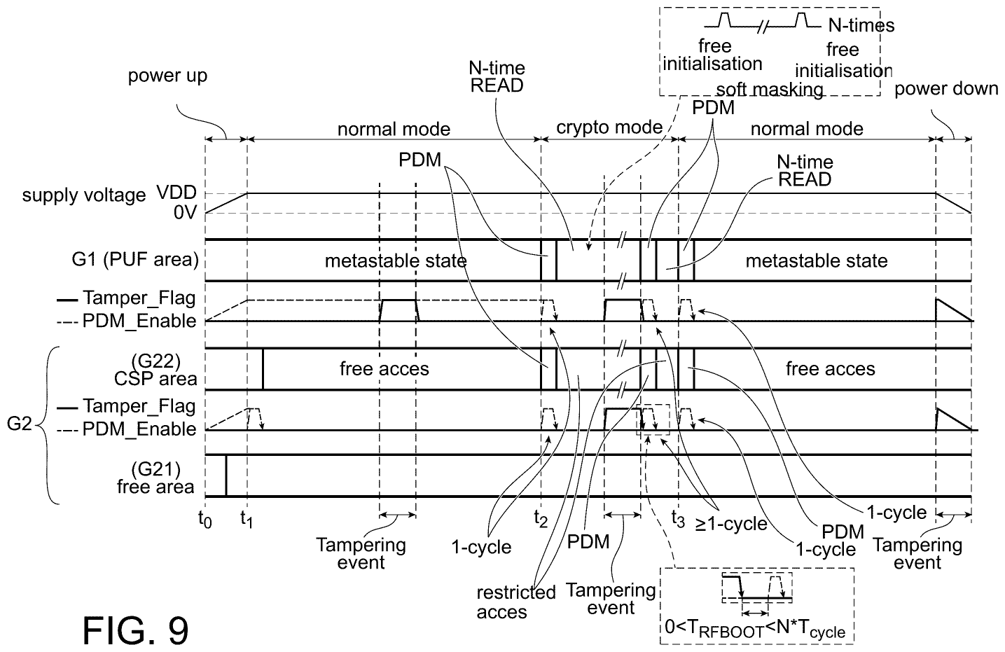

FIG. 9 gives an example of a time chart of the operation of a memory device which may be equipped with one or more initialisation control unit(s) as described before. The time scale on this time chart is not represented linearly, the ratio of the durations, respectively between the time points t1 and t2 and between the time points t2 and t3, being typically much higher than is the case in this schematic representation.

The start-up of the memory array is herein reflected by a passage of a conductive grid or line from 0 to VDD between a time point to and a time point t1. The cells of the first group G1 are then erased and then held in a metastable state whereas the cells of the subgroup G22 are initialised. The cells of the subgroup G22 will be initialised according to the default initialisation type provided for start-up. Thus, it is for example possible to provide for the cells of the set G22 having a random initialisation. To set the cells of the first group G1 in a metastable state, their high power supply line VDD (FIG. 8) is disconnected from a power supply conductive grid or line and/or their internal nodes N_{T} and N_{F} are connected to one another, for example by activating their access transistors TA_{T} and TA_{F} and by connecting together the bit rows BLTi, . . . , BLFi.

A falling edge on the activation signal PDM_ENABLE allows setting the control unit associated with the subgroup G22 of the CSP area in an unlocked state, whereas the control unit associated with the first group G1 remains in a locked state.

During a phase between a time point t1 and a time point t2, the device is in a so-called “normal” operating mode”, which corresponds to most of the overall operation time of the array when it is powered, for example at least 99% and in this example 99.9% of the time during which the power supply conductive grid is powered on and thus set at the power supply voltage VDD.

When the detection signal Tamper_flag is modified, for example following the detection of an intrusion or fraudulent access attempt (“tampering event”), the output(s) of the control unit associated with the first group G1 is or are not modified.

In the CSP area, it is possible to provide for not modifying the detection signal Tamper_flag in the NORMAL mode. Indeed, in this NORMAL mode, the data stored by this area are not considered to be sensitive and do not specifically require to be erased.

Then, starting from the time point t2, another so-called “crypto” mode is triggered. In particular, this operating mode may be an operating mode in which one wishes to access the cells of the first group G1 in order to carry out an enrolment procedure to determine the cells to be used to create a digital signature and/or an encryption key (PUF), or in order to read a digital signature and/or an encryption key contained in some cells of the first group G1. At a time point t2, the state of the activation signal PDM_ENABLE is such that it does not modify that of the output(s) of the control unit associated with the first group G1 of cells. Then, a falling edge on the activation signal PDM_ENABLE allows unlocking the control unit associated with the first group G1 of cells. During an “N-time READ” phase of the initialisations according to initialisation types that could be distinct from the default initialisation type may be launched. For example, it is possible to perform “free” type initialisations during this phase on the cells of the first group G1. During this time, the CSP area is in a restricted access mode.

This is possible in particular when each of the areas PUF and CSP uses its own control unit, the control unit of the area PUF could be distinct from the control unit of the area CSP.

During the crypto mode, an attempt of fraudulent access (“tampering event”) to the memory could possibly be detected and is reflected by a change in the state of the detection signal Tamper_flag which, for example through a switch into a given state, herein a high state corresponding to a logic ‘1’, allows launching a default initialisation of the cells of the first group G1 and of the cells of the subgroup G22. The control unit(s) associated with the first group G1 and with the subgroup G22 of cells are then set in a locked state. The cells of the first group G1 and of the cells of the subgroup G22 are then set in a metastable state.

An unlocking sequence (change in the state of the detection signal and then of the activation signal) then allows resetting the control unit associated with the first group G1 in an unlocked state, which again allows carrying out one or more initialisation(s) on the cells of the first group G1 according to respective types which may be distinct from that of the default initialisation.

Starting from a time point t3, a new change in the state of the activation signal could allow returning back into a “normal” operating mode. In particular, this state change may take place at the end of an enrolment operation or at the end of an operation of “interrogating” or “challenging” the area PUF in which the cells of the first group G1 could be located.

As a variant of an embodiment previously described in connection with FIG. 1, it can be considered that the locking of a memory area triggered by a particular sequence of signals is not carried out consecutively to a detection of fraudulent access but is done preventively. Thus, for example, instead of being generated by the intrusion detection module 11, the first logical signal TAMPER_FLAG referred to as ‘detection’, previously described and issued as an input to the initialization control unit 100, can come from another module than the previously mentioned fraudulent access detection module 11. For example, a microprocessor or a microcontroller, or a logic circuit external to the memory circuit, transmits to the initialization control unit 100 the first logical signal TAMPER_FLAG as a preventive measure, for instance, to protect a memory area or reserve privileged access to a memory area. The issuance of such a protection signal can be carried out potentially even before the memory is used, for example after its manufacturing and during a factory test conducted by an operator. This operator, having administrative rights over the memory, triggers the issuance of the logical signal TAMPER_FLAG by the aforementioned external module in order to generate a sequence enabling, for example, the locking of a particular memory area, for instance, of ROM type and/or containing a secret code.

1. A control unit of an SRAM memory for triggering an initialisation, selected among different possible distinct initialisation types, of at least one given group of SRAM memory cells of said SRAM memory, said control unit comprising:
a first hard masking input, able to receive a detection signal,
a second hard masking input, able to receive a activation signal,
one or more soft masking input(s) able to receive initialisation indicator signals according to different distinct initialisation types,
said control unit being configured to adopt a locked operating mode, in which, subsequently to a start-up of the memory and irrespective of the value of signals emitted on the first input and the second hard masking input and on the soft masking inputs, or subsequently to the reception of a so-called locking on said first soft masking input sequence,
said control unit produces at the output a so-called hard masking command signal able to trigger an initialisation of said given group of cells according to a default initialisation type corresponding to a first initialisation type from said different distinct initialisation types or an erasing, and holds at the output hard masking command signal in the same given state as long as a particular so-called unlocking signal sequence is not received on said hard masking inputs,
said control unit being further configured, subsequently to the reception of said particular unlocking signal sequence on said hard masking inputs, to adopt at least one other operating mode in which, in the absence of new signals or a change in the state of the signals on said hard masking inputs, when said control unit receives an initialisation indicator signal of the first initialisation type, to produce at the output an initialisation command signal of the first type to trigger an initialisation of the memory cells of said given group of cells according to said first initialisation type and when the control unit receives an initialisation indicator signal of the second initialisation type, to produce at the output an initialisation command signal of a second type to trigger an initialisation of the memory cells of said given group of cells according to said second initialisation type.

2. The control unit according to claim 1, wherein said detection signal originates from a module for detecting fraudulent access to said SRAM memory, said locking sequence on said first hard masking input corresponding to a change in the state of said detection signal.

3. The control unit according to claim 1, wherein said unlocking sequence consists, in that order, of a given logic state or a change in the logic state of said detection signal on said first hard masking input into said given logic state and then, a change in the activation signal on said second hard masking input.

4. The control unit according to claim 1, further configured, in said at least one other operating mode, subsequently to the reception of said activation signal on the second “hard masking” input and in the absence of a change in the state of the detection signal on the first “hard masking” input, to emit a hard masking command signal to trigger an initialisation of the memory cells of said given group according to said default initialisation type.

5. The control unit according to claim 1, wherein the control unit is equipped with an asynchronous flip-flop logic module having a so-called “control” input coupled to the first hard masking input and another so-called “control” input coupled to the second hard masking input, said logic module being configured, subsequently to a start-up or to the reception of said locking sequence, to hold at the output a first logic state as long as said logic module does not receive said unlocking sequence and, subsequently to the reception of said unlocking sequence, to produce at the output a second logic state complementary of said first logic state.

6. The control unit according to claim 5, further comprising a logic gate stage coupled to an output of said logic module and to said soft masking inputs, said logic gate stage being equipped with:
at least one first logic gate ensuring a given logic function, in particular ensuring an OR function between a first soft masking input and the complementary of an output of said logic module, an output of the first logic gate being coupled to a first output of the control unit intended to output the initialisation command signal of the first type,
at least one second logic gate ensuring a logic function distinct from the given logic function, in particular ensuring an AND function between a second input of said plurality of soft masking inputs and the output of said logic module being coupled to a second output of the control unit intended to output the initialisation command signal of the second type.

7. The control unit according to claim 5, wherein the logic module with an asynchronous flip-flop is equipped with an asymmetrical asynchronous flip-flop such as an asymmetrical RS flip-flop.

8. The control unit according to claim 7, wherein said asynchronous flip-flop is formed of a first set of transistors ensuring a given logic function, in particular a NOR function or a NAND function, and of a second set of transistors ensuring said same given logic function, said asynchronous flip-flop being asymmetrical so that said first set of transistors is equipped with at least one first group of transistors having an arrangement similar to that of a second group of transistors of said second set of transistors, the transistors of the first group being provided with a threshold voltage or a size different from that of the transistors of said second group.

9. The control unit according to claim 1, wherein among said soft masking inputs:
a first soft masking input is able to receive an initialisation indicator signal of a first initialisation type,
a second soft masking input, able to receive an initialisation indicator signal of a second initialisation type among said different initialisation types, the second initialisation type being distinct from said first initialisation type and from said second initialisation type,
a third soft masking input, able to receive an initialisation indicator signal of a third initialisation type among said different initialisation types, the third initialisation type being distinct from said first initialisation type and from said second initialisation type,
wherein in said at least one other operating mode when the third soft masking input receives an initialisation indicator signal of the third initialisation type, the control unit produces at the input an initialisation command of a third type to trigger an initialisation of the memory cells of said given group of cells according to said third initialisation type.

10. The control unit according to claim 1, the first initialisation type and the second initialisation type are of distinct initialisation types among:
a 1 setting type initialisation or 0 setting type initialisation consisting in setting all of the cells of said group at the same logic state,
a random type initialisation consisting in imposing on each column of cells of said group the same given logic state randomly selected from a first logic state and a second logic state,
a free type initialisation consisting in setting the internal nodes of each cell of said group at the same potential and then letting these internal nodes be respectively charged or uncharged in order to let the cell freely settle at a given logic state.

11. The control unit according to claim 1, wherein, in the locked operating mode, said holding at the output of said hard masking command signal in the same given state is able to hold said given group of cells in a metastable undetermined state for which their respective first storage node and second storage node are set at equal or substantially equal potentials.

12. A static random-access memory device comprising:
a set of SRAM cells comprising said given group of SRAM cells,
at least one first control unit according to claim 1, for initialising said given group of said set of SRAM cells.

13. The static random-access memory device according to claim 12, further comprising:
controlling the initialisation, according to different possible distinct initialisation types, of the memory cells of a second group of cells of said set of SRAM memory cells distinct from said given group.

14. The static random-access memory device according to claim 12, wherein said given group of cells contains a physical unclonable function (PUF), said second group of cells corresponding to sensitive data storage cells or to free-access cells.

15. The static random-access memory device according to claim 11, wherein the second control unit is configured, subsequently to each start-up of the memory or subsequently to the reception of a locking signal, to produce at the output an initialisation command signal to trigger an initialisation of said second group of cells according to a default initialisation type among said different distinct initialisation types, the default initialisation type of the second control unit being different from the default initialisation type of the first control unit and selected among:
a 1 setting type initialisation or 0 setting type initialisation consisting in setting all of the cells of said group at the same logic state,
a random deterministic type initialisation consisting in imposing on each column of cells of said group the same given logic state selected by random sorting from a first logic state and a second logic state,
a free type initialisation consisting in setting the internal nodes of each cell of said group at the same potential and then letting these internal nodes be respectively charged or uncharged in order to let the cell freely settle at a given logic state.

16. The static random-access memory device according to claim 15, the default initialisation type of the first control unit being a 1 setting type initialisation or 0 setting type initialisation consisting in setting all of the cells of said group at the same logic state, the default initialisation type of the second control unit being a random deterministic type initialisation consisting in imposing on each column of cells of said group the same given logic state randomly selected from a first logic state and a second logic state.
